(19) United States
(12) Patent Application Publication
(10) Pub. No.: US 2024/0112918 A1
(43) Pub. Date: Apr. 4, 2024

(54) PLASMA PROCESSING SYSTEM, PLASMA PROCESSING APPARATUS, AND ETCHING METHOD

(71) Applicant: Tokyo Electron Limited, Tokyo (JP)

(72) Inventors: Noboru SAITO, Kurokawa-gun (JP); Yuta NAKANE, Kurokawa-gun (JP); Atsushi TAKAHASHI, Kurokawa-gun (JP); Shinya ISHIKAWA, Kurokawa-gun (JP); Satoshi OHUCHIDA, Kurokawa-gun (JP); Maju TOMURA, Kurokawa-gun (JP)

(21) Appl. No.: 18/479,986

(22) Filed: Oct. 3, 2023

(30) Foreign Application Priority Data
Oct. 4, 2022 (JP) 2022-160438
Sep. 27, 2023 (JP) 2023-164185

(51) Int. Cl. H01L 21/3065; H01J 37/32; H01L 21/308; H01L 21/311

(52) U.S. Cl. CPC H01L 21/3065; H01J 37/32009; H01J 37/32899; H01L 21/308; H01L 21/31144

(57) ABSTRACT

A plasma processing system includes: first and second processing chambers having respective first and second substrate supports; a transport chamber connected to the first and second processing chambers, and having a transport device; and a controller that executes processing of (a) disposing a substrate including a silicon-containing film having a recess portion and a mask on the silicon-containing film on the first substrate support of the first processing chamber, (b) forming a carbon-containing film on a side wall of the silicon-containing film defining the recess portion in the first processing chamber, (c) transporting the substrate from the first processing chamber to the second processing chamber via the transport chamber and disposing the substrate on the second substrate support, and (d) etching a bottom portion of the recess portion where the carbon-containing film is formed by using a plasma formed from a first processing gas in the second processing chamber.

### CROSS-REFERENCE TO RELATED APPLICATION

The present application claims priority under 35 U.S.C. § 119 to Japanese Patent Application No. 2022-160438 filed on Oct. 4, 2022 and Japanese Patent Application No. 2023-164185 filed on Sep. 27, 2023, the entire contents of which are incorporated herein by reference.

### BACKGROUND

### Field

Exemplary embodiments of the present disclosure relate to a plasma processing system, a plasma processing apparatus, and an etching method.

### Description of Related Art

Japanese Patent Application Laid-Open No. 2016-21546 discloses an etching method of a substrate in which a polysilicon mask is formed on a silicon-containing film.

### SUMMARY

The present disclosure provides a technology for suppressing a shape abnormality in etching.

In one exemplary embodiment of the present disclosure, a plasma processing system is provided. The plasma processing system includes: a first processing chamber having a first substrate support; a second processing chamber that has a second substrate support and is different from the first processing chamber; a transport chamber that is connected to the first processing chamber and the second processing chamber, and has a transport device; and a controller, in which the controller executes (a) processing of disposing a substrate including a silicon-containing film having a recess portion and a mask on the silicon-containing film on the first substrate support of the first processing chamber, in which the mask has an opening that exposes the recess portion, (b) processing of forming a carbon-containing film on a side wall of the silicon-containing film defining the recess portion in the first processing chamber, (c) processing of transporting the substrate from the first processing chamber to the second processing chamber via the transport chamber and disposing the substrate on the second substrate support, and (d) processing of etching a bottom portion of the recess portion where the carbon-containing film is formed by using a plasma formed from a first processing gas containing a hydrogen fluoride gas in the second processing chamber.

### BRIEF DESCRIPTION OF DRAWINGS

FIG. 1 is a diagram schematically illustrating a configuration example of a plasma processing system.

FIG. 2 is a diagram for describing a configuration example of a capacitively coupled plasma processing apparatus.

FIG. 3 is a diagram for describing a configuration example of an inductively coupled plasma processing apparatus.

FIG. 4 is a flowchart illustrating a plasma processing method according to an exemplary embodiment.

FIG. 5 is a diagram illustrating an example of a cross-sectional structure of a substrate provided in step ST11.

FIG. 6 is a diagram illustrating an example of a cross-sectional structure of the substrate after the processing in step ST12.

FIG. 7 is a diagram illustrating an example of a cross-sectional structure of the substrate after the processing in step ST2.

FIG. 8A is a diagram illustrating another example of the cross-sectional structure of the substrate after the processing in step ST2.

FIG. 8B is a diagram illustrating an example of the cross-sectional structure of the substrate after a breakthrough step.

FIGS. 9A and 9B are diagrams illustrating an example of the cross-sectional structure of the substrate during the processing in step ST3.

FIG. 10 is a flowchart illustrating another example of the present processing method.

### DETAILED DESCRIPTION

Hereinafter, each embodiment of the present disclosure will be described.

In one exemplary embodiment, a plasma processing system is provided. The plasma processing system includes: a first processing chamber having a first substrate support; a second processing chamber that has a second substrate support and is different from the first processing chamber; a transport chamber that is connected to the first processing chamber and the second processing chamber, and has a transport device; and a controller, in which the controller executes (a) processing of disposing a substrate including a silicon-containing film having a recess portion and a mask on the silicon-containing film on the first substrate support of the first processing chamber, in which the mask has an opening that exposes the recess portion, (b) processing of forming a carbon-containing film on a side wall of the silicon-containing film defining the recess portion in the first processing chamber, (c) processing of transporting the substrate from the first processing chamber to the second processing chamber via the transport chamber and disposing the substrate on the second substrate support, and (d) processing of etching a bottom portion of the recess portion where the carbon-containing film is formed by using a plasma formed from a first processing gas containing a hydrogen fluoride gas in the second processing chamber.

In one exemplary embodiment, the controller executes processing of repeating a cycle including (a), (b), (c), and (d) a plurality of times.

In one exemplary embodiment, at least in (c), the controller controls a pressure in the transport chamber so that the pressure in the transport chamber is lower than a pressure in the first processing chamber and a pressure in the second processing chamber.

In one exemplary embodiment, the controller executes processing of forming the recess portion on the silicon-containing film and preparing the substrate including the silicon-containing film having the recess portion by etching using a plasma formed from a second processing gas containing a fluorine-containing gas in the second processing chamber or in a third processing chamber different from the second processing chamber before (a).

In one exemplary embodiment, a temperature of the first substrate support in the processing of (b) is higher than a temperature of the second substrate support in the processing of (c).

In one exemplary embodiment, the controller executes processing of forming the carbon-containing film with a third processing gas containing a carbon-containing gas in (b).

In one exemplary embodiment, the carbon-containing gas is a hydrocarbon gas.

In one exemplary embodiment, the third processing gas further contains a nitrogen-containing gas.

In one exemplary embodiment, in (b), the controller executes processing including (b11) a step of supplying a precursor gas to the substrate and adsorbing the precursor gas to the side wall, and (b12) a step of supplying a reaction gas to the substrate and forming the carbon-containing film by a reaction between the precursor gas and the reaction gas.

In one exemplary embodiment, (b) includes (b1) a step of supplying a first film formation gas containing a first organic compound into the first processing chamber, and (b2) a step of supplying a second film formation gas containing a second organic compound different from the first organic compound into the first processing chamber.

In one exemplary embodiment, (b2) forms the carbon-containing film by a reaction including polymerization of the first organic compound and the second organic compound.

In one exemplary embodiment, (d) further includes processing of enlarging a dimension of the portion that is etched in (d) in the recess portion.

In one exemplary embodiment, the first processing gas further contains a phosphorus-containing gas.

In one exemplary embodiment, the first processing gas further contains at least one gas selected from the group consisting of a carbon-containing gas, a halogen-containing gas, and a metal-containing gas.

In one exemplary embodiment, the processing of (d) is executed at a temperature of the second substrate support which is 0° C. or lower.

In one exemplary embodiment, the first processing chamber is coupled to an inductively coupled plasma generator, the second processing chamber is coupled to a capacitively coupled plasma generator, and in the processing of (b), the controller executes processing of forming a plasma by the inductively coupled plasma generator to form the carbon-containing film, and in the processing of (d), the controller executes processing of forming plasma by the capacitively coupled plasma generator to etch the silicon-containing film.

In one exemplary embodiment, the silicon-containing film is a silicon oxide film, a silicon nitride film, a polycrystalline silicon film, or a stacked film including two or more of these.

In one exemplary embodiment, the mask is a carbon-containing film or a metal-containing film.

In one exemplary embodiment, a plasma processing system is provided. The plasma processing system includes: a first processing chamber having a first substrate support; a second processing chamber that has a second substrate support and is different from the first processing chamber; a transport chamber that is connected to the first processing chamber and the second processing chamber, and has a transport device; and a controller, in which the controller includes (a) processing of disposing a substrate including a silicon-containing film having a recess portion and a mask on the silicon-containing film on the first substrate support of the first processing chamber, in which the mask has an opening that exposes the recess portion, (b) processing of forming a carbon-containing film on a side wall of the silicon-containing film defining the recess portion in the first processing chamber, (c) processing of transporting the substrate from the first processing chamber to the second processing chamber via the transport chamber and disposing the substrate on the second substrate support, and (d) processing of etching a bottom portion of the recess portion where the carbon-containing film is formed in the second processing chamber, and the processing of (d) executes processing of repeating a cycle including (d1) a step of exposing the substrate to a plasma formed from a fourth processing gas containing a hydrogen fluoride gas, (d2) a step of exposing the substrate to a plasma formed from a fifth processing gas containing a fluorocarbon gas and/or a hydrofluorocarbon gas, and (d3) a step of exposing the substrate to a plasma formed from a sixth processing gas containing a hydrogen-containing gas.

In one exemplary embodiment, a plasma processing apparatus is provided. The plasma processing apparatus includes a chamber; a substrate support disposed in the chamber; a plasma generator; and a controller, in which the controller executes (a) processing of disposing a substrate including a silicon-containing film having a recess portion and a mask, which has an opening exposing the recess portion, on the silicon-containing film on the substrate support, (b) processing of forming a carbon-containing film on a side wall of the silicon-containing film defining the recess portion in the chamber, and (c) processing of etching a bottom portion of the recess portion where the carbon-containing film is formed, by using a plasma formed from a processing gas containing a hydrogen fluoride gas in the chamber.

In one exemplary embodiment, an etching method is provided. The etching method includes (a) a step of disposing a substrate including a silicon-containing film having a recess portion and a mask, which has an opening exposing the recess portion, on the silicon-containing film on a first substrate support of a first processing chamber; (b) a step of forming a carbon-containing film on a side wall of the silicon-containing film defining the recess portion in the first processing chamber; and (c) a step of transporting the substrate from the first processing chamber to a second processing chamber via a transport chamber and disposing the substrate on a second substrate support of the second processing chamber, and (d) a step of etching a bottom portion of the recess portion where the carbon-containing film is formed, by using a plasma formed from a processing gas containing a hydrogen fluoride gas in the second processing chamber.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### <Configuration Example of Plasma Processing System>

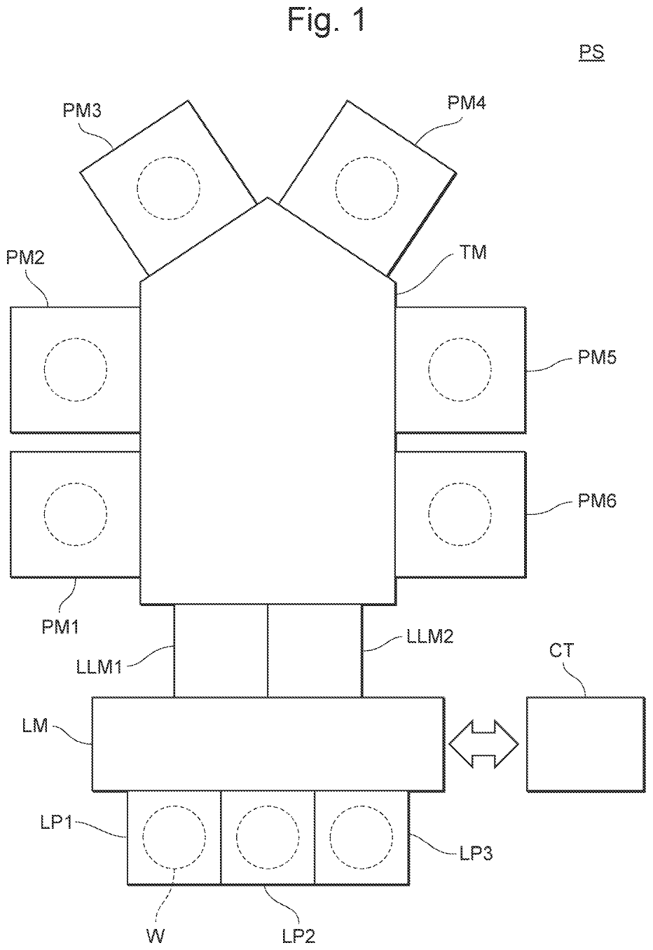

FIG. 1 is a diagram schematically illustrating an example of a plasma processing system (hereinafter, referred to as a “substrate processing system PS”).

The substrate processing system PS includes substrate processing chambers PM1 to PM6 (hereinafter, also collectively referred to as a “substrate processing module PM”), a transport module TM, and load lock modules LLM1 and LLM2 (hereinafter, also collectively referred to as a “load lock module LLM”), a loader module LM, and load ports (LP1 to LP3) (hereinafter, also collectively referred to as a “load port LP”). A controller CT controls each configuration of the substrate processing system PS to execute given processing on a substrate W.

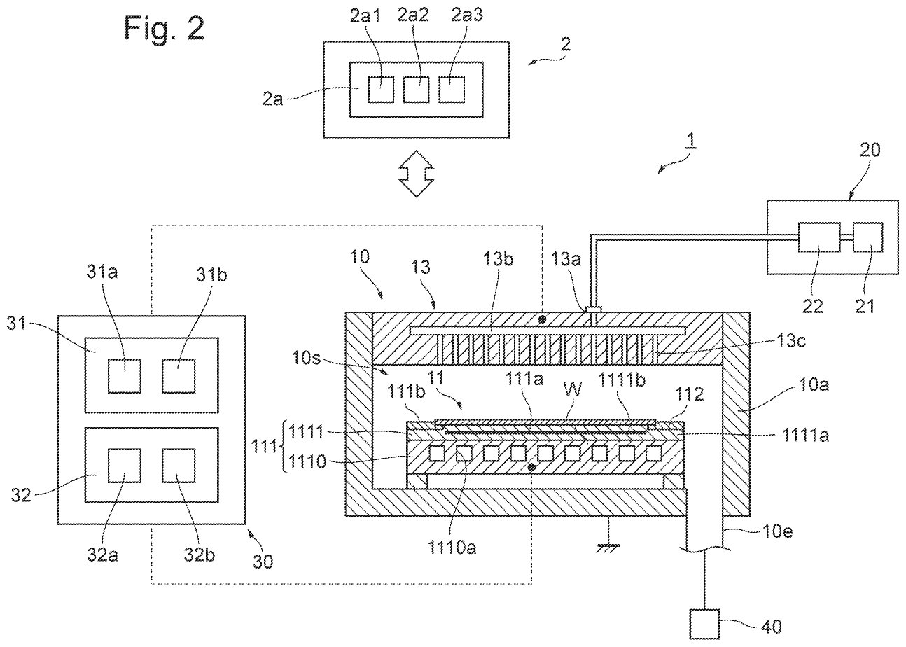

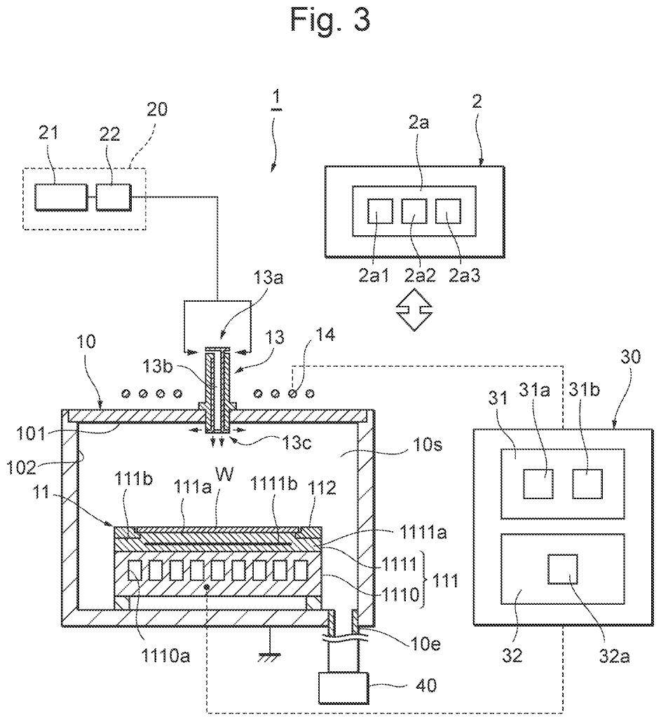

In the substrate processing module PM, etching processing, trimming processing, film formation processing, annealing processing, doping processing, lithography processing, cleaning processing, ashing processing, and the like are executed on the substrate W. A part of the substrate processing module PM may be a capacitively coupled plasma processing apparatus as illustrated in FIG. 2. That is, at least one of the substrate processing chambers PM1 to PM6 may be coupled to a capacitively coupled plasma generator. A part of the substrate processing module PM may be an inductively coupled plasma processing apparatus as illustrated in FIG. 3. That is, at least one of the substrate processing chambers PM1 to PM6 may be coupled to an inductively coupled plasma generator. A part of the substrate processing module PM may be a measurement module, and a film thickness of a film formed on the substrate W, dimensions of a pattern formed on the substrate W, and the like may be measured by using, for example, an optical method.

The transport module TM has a transport device that transports the substrate W and transports the substrate W between the substrate processing modules PM or between the substrate processing module PM and the load lock module LLM. The substrate processing module PM and the load lock module LLM are disposed adjacent to the transport module TM. The transport module TM, the substrate processing module PM, and the load lock module LLM are spatially separated or connected by a gate valve that can be opened and closed.

The load lock modules LLM1 and LLM2 are provided between the transport module TM and the loader module LM. The load lock module LLM can switch a pressure therein to an atmospheric pressure or a vacuum. The “atmospheric pressure” may be an external pressure of each module included in the substrate processing system PS. In addition, the “vacuum” is a pressure lower than the atmospheric pressure, and may be, for example, a medium vacuum of 0.1 Pa to 100 Pa. The load lock module LLM transports the substrate W from the loader module LM which has the atmospheric pressure to the transport module TM which has the vacuum, and also transports the substrate W from the transport module TM which has the vacuum to the loader module LM which has the atmospheric pressure.

The loader module LM has a transport device for transporting the substrate W, and transports the substrate W between the load lock module LLM and the load port LP. For example, a front opening unified pod (FOUP) capable of accommodating 25 substrates W or an empty FOUP can be placed in the load port LP. The loader module LM takes out the substrate W from the FOUP in the load port LP and transports the substrate W to the load lock module LLM. Further, the loader module LM takes out the substrate W from the load lock module LLM and transports the substrate W to the FOUP in the load port LP.

The controller CT controls each configuration of the substrate processing system PS to execute given processing on the substrate W. The controller CT stores a recipe in which a process procedure, a process condition, a transport condition, and the like are set, and controls each configuration of the substrate processing system PS to execute given processing on the substrate W according to the recipe. The controller CT may also function as a part or all of a controller 2 illustrated in FIG. 2 or 3.

### <Configuration Example of Capacitively Coupled Plasma Processing Apparatus>

Hereinafter, a configuration example of the capacitively coupled plasma processing apparatus as an example of the plasma processing apparatus 1 will be described.

FIG. 2 is a diagram for describing a configuration example of the capacitively coupled plasma processing apparatus. The plasma processing apparatus 1 includes a plasma processing chamber 10, a gas supply 20, a power supply 30, and an exhaust system 40. In addition, the plasma processing apparatus 1 includes a substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an embodiment, the shower head 13 is configured to form at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 has at least one gas supply port for supplying at least one processing gas to the plasma processing space 10s, and at least one gas exhaust port for exhausting the gas from the plasma processing space 10s. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a center region 111a for supporting the substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 so as to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has a center region 111a. In an embodiment, the ceramic member 1111a also has an annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. In addition, at least one RF/DC electrode coupled to a radio frequency (RF) power supply 31 and/or a direct current (DC) power supply 32, which will be described later, may be disposed in the ceramic member 1111a. In this case, at least one RF/DC electrode functions as the lower electrode. When a bias RF signal and/or a DC signal, which will be described later, are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Therefore, the substrate support 11 includes at least one lower electrode.

The ring assembly 112 includes one or a plurality of annular members. In an embodiment, one or the plurality of annular members includes one or a plurality of edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow path 1110a, or a combination thereof. A heat transfer fluid such as brine or a gas flows in the flow path 1110a. In an embodiment, the flow path 1110a is formed in the base 1110, and one or a plurality of heaters are disposed in the ceramic member 1111a of the electrostatic chuck 1111. Further, the substrate support 11 may include a heat transfer gas supply configured to supply the heat transfer gas to a gap between a back surface of the substrate W and the center region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. In addition to the shower head 13, the gas introducer may include one or a plurality of side gas injectors (SGI) attached to one or a plurality of opening portions formed on the side wall 10a.

The gas supply 20 may include at least one gas source 21 and at least one flow rate controller 22. In an embodiment, the gas supply 20 is configured to supply at least one processing gas from the gas sources 21 each corresponding thereto to the shower head 13 via the flow rate controllers 22 each corresponding thereto. Each flow rate controller 22 may include, for example, a mass flow controller or a pressure-controlled flow rate controller. Further, the gas supply 20 may include one or more flow rate modulation devices that modulate or pulse the flow rate of at least one processing gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. As a result, plasma is formed from at least one processing gas supplied to the plasma processing space 10s. Therefore, the RF power supply 31 may function as at least a part of the plasma generator configured to form the plasma from one or more processing gases in the plasma processing chamber 10. Further, by supplying the bias RF signal to at least one lower electrode, a bias potential is generated in the substrate W, and an ion component in the formed plasma can be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma generation. In an embodiment, the source RF signal has a frequency in a range of 10 MHz to 150 MHz. In an embodiment, the first RF generator 31a may be configured to generate a plurality of source RF signals having different frequencies. The generated one or plurality of source RF signals are supplied to at least one lower electrode and/or at least one upper electrode.

The second RF generator 31b is coupled to at least one lower electrode via at least one impedance matching circuit and is configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in a range of 100 kHz to 60 MHz. In an embodiment, the second RF generator 31b may be configured to generate a plurality of bias RF signals having different frequencies. The generated one or plurality of bias RF signals are supplied to at least one lower electrode. In addition, in various embodiments, at least one of the source RF signal and the bias RF signal may be pulsed.

Further, the power supply 30 may include a DC power supply 32 coupled to the plasma processing chamber 10. The DC power supply 32 includes a first DC generator 32a and a second DC generator 32b. In an embodiment, the first DC generator 32a is connected to at least one lower electrode, and is configured to generate the first DC signal. The generated first bias DC signal is applied to at least one lower electrode. In an embodiment, the second DC generator 32b is connected to at least one upper electrode and is configured to generate a second DC signal. The generated second DC signal is applied to at least one upper electrode.

In various embodiments, at least one of the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. When the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or a plurality of positive voltage pulses and one or a plurality of negative voltage pulses in one cycle. The first and second DC generators 32a and 32b may be provided in addition to the RF power supply 31, and the first DC generator 32a may be provided in place of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

### <Configuration Example of Inductively Coupled Plasma Processing Apparatus>

Next, a configuration example of the inductively coupled plasma processing apparatus as an example of the plasma processing apparatus 1 will be described. FIG. 3 is a diagram for describing the configuration example of the inductively coupled plasma processing apparatus.

The inductively coupled plasma processing apparatus 1 includes the plasma processing chamber 10, the gas supply 20, the power supply 30, and the exhaust system 40. The plasma processing chamber 10 includes a dielectric window 101. In addition, the plasma processing apparatus 1 includes the substrate support 11, the gas introducer, and an antenna 14. The substrate support 11 is disposed in the plasma processing chamber 10. The antenna 14 is disposed on or above the plasma processing chamber 10 (that is, on or above the dielectric window 101). The plasma processing chamber 10 has the plasma processing space 10s defined by the dielectric window 101, the side wall 102 of the plasma processing chamber 10, and the substrate support 11. The plasma processing chamber 10 is grounded.

The substrate support 11 includes the main body 111 and the ring assembly 112. The main body 111 has a center region 111a for supporting the substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 so as to surround the substrate Won the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes the base 1110 and the electrostatic chuck 1111. The base 1110 includes a conductive member. The conductive member of the base 1110 may function as a bias electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has a center region 111a. In an embodiment, the ceramic member 1111a also has an annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. Further, at least one RF/DC electrode coupled to the RF power supply 31 and/or the DC power supply 32, which will be described later, may be disposed in the ceramic member 1111a. In this case, at least one RF/DC electrode functions as the bias electrode. The conductive member of the base 1110 and at least one RF/DC electrode may function as a plurality of bias electrodes. Further, the electrostatic electrode 1111b may function as the bias electrode. Therefore, the substrate support 11 includes at least one bias electrode.

The ring assembly 112 includes one or a plurality of annular members. In an embodiment, one or the plurality of annular members includes one or a plurality of edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow path 1110a, or a combination thereof. A heat transfer fluid such as brine or a gas flows in the flow path 1110a. In an embodiment, the flow path 1110a is formed in the base 1110, and one or a plurality of heaters are disposed in the ceramic member 1111a of the electrostatic chuck 1111. Further, the substrate support 11 may include a heat transfer gas supply configured to supply the heat transfer gas to a gap between a back surface of the substrate W and the center region 111a.

The gas introducer is configured to introduce at least one processing gas from the gas supply 20 into the plasma processing space 10s. In an embodiment, the gas introducer includes a center gas injector (CGI) 13. The center gas injector 13 is disposed above the substrate support 11 and is attached to a center opening portion formed in the dielectric window 101. The center gas injector 13 has at least one gas supply port 13a, at least one gas flow path 13b, and at least one gas introduction port 13c. The processing gas supplied to the gas supply port 13a passes through the gas flow path 13b and is introduced into the plasma processing space 10s from the gas introduction port 13c. In addition, the gas introducer may include one or a plurality of side gas injectors (SGI: side gas injector) attached to one or a plurality of opening portions formed in the side wall 102 in addition to or instead of the center gas injector 13.

The gas supply 20 may include at least one gas source 21 and at least one flow rate controller 22. In an embodiment, the gas supply 20 is configured to supply at least one processing gas from the gas sources 21 each corresponding thereto to the gas introducer via the flow rate controllers 22 each corresponding thereto. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one bias electrode and the antenna 14. As a result, plasma is formed from at least one processing gas supplied to the plasma processing space 10s. Therefore, the RF power supply 31 may function as at least a part of the plasma generator 12. Further, by supplying the bias RF signal to at least one bias electrode, the bias potential is generated on the substrate W, and ions in the formed plasma can be drawn into the substrate W.

In an embodiment, the RF power supply 31 includes the first RF generator 31a and the second RF generator 31b. The first RF generator 31a is coupled to the antenna 14 via at least one impedance matching circuit and is configured to generate the source RF signal (source RF power) for plasma generation. In an embodiment, the source RF signal has a frequency in a range of 10 MHz to 150 MHz. In an embodiment, the first RF generator 31a may be configured to generate a plurality of source RF signals having different frequencies. The generated one or plurality of source RF signals are supplied to the antenna 14.

The second RF generator 31b is coupled to at least one bias electrode via at least one impedance matching circuit and generates the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in a range of 100 kHz to 60 MHz. In an embodiment, the second RF generator 31b may be configured to generate a plurality of bias RF signals having different frequencies. The generated one or plurality of bias RF signals are supplied to at least one bias electrode. In addition, in various embodiments, at least one of the source RF signal and the bias RF signal may be pulsed.

Further, the power supply 30 may include the DC power supply 32 coupled to the plasma processing chamber 10. The DC power supply 32 includes the bias DC generator 32a. In an embodiment, the bias DC generator 32a is connected to at least one bias electrode and is configured to generate the bias DC signal. The generated bias DC signal is applied to at least one bias electrode.

In various embodiments, the bias DC signal may be pulsed. In this case, the sequence of voltage pulses is applied to at least one bias electrode. The voltage pulse may have a pulse waveform having a rectangular shape, a trapezoidal shape, a triangular shape, or a combination thereof. In an embodiment, the waveform generator for generating the sequence of voltage pulses from the DC signal is connected between the bias DC generator 32a and at least one bias electrode. Therefore, the bias DC generator 32a and the waveform generator configure the voltage pulse generator. The voltage pulse may have a positive polarity or a negative polarity. In addition, the sequence of voltage pulses may include one or a plurality of positive voltage pulses and one or a plurality of negative voltage pulses in one cycle. The bias DC generator 32a may be provided in addition to the RF power supply 31 or may be provided in place of the second RF generator 31b.

The antenna 14 includes one or a plurality of coils. In an embodiment, the antenna 14 may include an outer coil and an inner coil disposed coaxially. In this case, the RF power supply 31 may be connected to both an outer coil and an inner coil, or may be connected to one of the outer coil and the inner coil. In the former case, the same RF generator may be connected to both the outer coil and the inner coil, or separate RF generators may be connected to the outer coil and the inner coil separately.

The exhaust system 40 may be connected to, for example, the gas exhaust port 10e provided at the bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

### <Example of Plasma Processing Method>

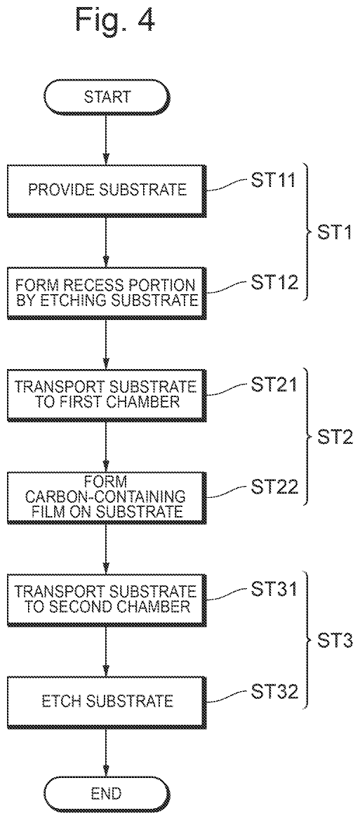

FIG. 4 is a flowchart illustrating an example of a plasma processing method (hereinafter, also referred to as “present processing method”) according to one exemplary embodiment. As illustrated in FIG. 4, the present processing method includes a step ST1 of preparing a substrate, a step ST2 of forming a carbon-containing film on the substrate, and a step ST3 of etching the substrate. The processing in each step may be executed in two or more of a plurality of substrate processing modules PM included in the substrate processing system PS illustrated in FIG. 1. The substrate processing module PM may be the plasma processing apparatus 1 illustrated in FIG. 2 and/or FIG. 3. Then, for example, step ST1 and step ST3 may be executed in the capacitively coupled plasma processing apparatus 1 illustrated in FIG. 2 and step ST2 may be executed in the inductively coupled plasma processing apparatus 1 illustrated in FIG. 3. Hereinafter, a case where the controller 2 controls each unit of the substrate processing system PS and the plasma processing apparatus 1 to execute the present processing method on the substrate W will be described as an example.

### (Step ST1: Preparation of Substrate)

As illustrated in FIG. 4, step ST11 includes step ST11 to provide the substrate W and step ST12 to etch the substrate W to form a recess portion. First, in step ST11, the substrate W is provided in the plasma processing space 10s of the capacitively coupled plasma processing apparatus 1 illustrated in FIG. 2. The substrate W is provided on the center region 111a of the substrate support 11. Then, the substrate W is held by the substrate support 11 by the electrostatic chuck 1111.

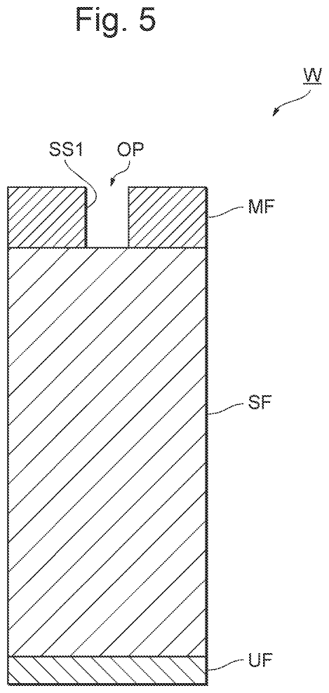

FIG. 5 is a diagram illustrating an example of a cross-sectional structure of the substrate W provided in step ST11. As illustrated in FIG. 5, the substrate W has a silicon-containing film SF and a mask MK formed on the silicon-containing film SF. The silicon-containing film SF may be formed on an underlying film UF. The substrate W may be used for manufacturing a semiconductor device. The semiconductor device includes, for example, a semiconductor memory device such as DRAM or 3D-NAND flash memory.

The underlying film UF is, for example, a silicon wafer, an organic film, a dielectric film, a metal film, a semiconductor film, or the like formed on the silicon wafer. The underlying film UF may be configured by stacking a plurality of films.

The silicon-containing film SF is a film to be etched by the present processing method. The silicon-containing film SF may be, for example, a silicon oxide film, a silicon nitride film, a silicon acid nitride film, a silicon carbon nitride film, a polycrystalline silicon film, or a carbon-containing silicon film. The silicon-containing film SF may be configured by stacking a plurality of films. For example, the silicon-containing film SF may be configured by alternately stacking the silicon oxide film and the silicon nitride film. For example, the silicon-containing film SF may be configured by alternately stacking the silicon oxide film and the polycrystalline silicon film. For example, the silicon-containing film SF may be a stacked film including the silicon nitride film, the silicon oxide film, and the polycrystalline silicon film. For example, the silicon-containing film SF may be configured by stacking the silicon oxide film and the silicon carbon nitride film. For example, the silicon-containing film SF may be a stacked film including the silicon oxide film, the silicon nitride film, and the silicon carbon nitride film. The silicon-containing film may include at least one element selected from the group consisting of phosphorus (P), nitrogen (N), and boron (B).

The mask MK is formed from a material having an etching rate lower than that of the silicon-containing film SF with respect to the plasma formed in step ST12 or step ST3. The mask MK may be formed from, for example, the carbon-containing material. In an example, the mask MK is an amorphous carbon film, a photoresist film, or an SOC film (spin-on carbon film). The mask MK may be, for example, a metal-containing film containing at least one metal selected from the group consisting of tungsten, molybdenum, titanium, and ruthenium. In an example, the mask MK includes tungsten carbide or tungsten silicide. The mask MK may be a single-layer mask including one layer, or may be a multilayer mask including two or more layers.

As illustrated in FIG. 5, the mask MK defines at least one opening OP on the silicon-containing film SF. The opening OP is a space on the silicon-containing film SF and is surrounded by a side wall SS1 of the mask MK. That is, an upper surface of the silicon-containing film SF has a region covered by the mask MK and a region exposed at a bottom portion of the opening OP.

The opening OP may have any shape in a plan view of the substrate W, that is, when the substrate W is viewed in a direction from the top to the bottom of FIG. 3. The shape may be, for example, a circle, an ellipse, a rectangle, a line, or a shape in which one or more of these are combined. The mask MK may have a plurality of side walls SS1 and the plurality of side walls SS1 may define a plurality of openings OP. The plurality of openings OP may each have a linear shape and may be arranged at regular intervals to form a line & space pattern. Further, the plurality of openings OP may each have a hole shape and may form an array pattern.

Each of the films (underlying film UF, silicon-containing film SF, and mask MK) constituting the substrate W may be formed by a CVD method, an ALD method, a spin coating method, or the like. The mask MK may be formed by lithography. Further, the opening OP of the mask MK may be formed by etching the mask MK. Each of the films may be a flat film or a film having irregularities. The substrate W may further have another film under the underlying film UF. In this case, a recess portion having a shape corresponding to the opening OP may be formed in the silicon-containing film SF and the underlying film UF, and used as a mask for etching the other films.

At least a part of the process of forming each film of the substrate W may be executed in the space of the plasma processing chamber 10 where step ST1 is executed. In an example, when the mask MK is etched to form the opening OP, the step may be executed in the plasma processing chamber 10. That is, the etching of the opening OP and the silicon-containing film SF in step ST12, which will be described later, may be continuously executed in the same chamber. Further, after the entire film of the substrate W is formed by an external device or a chamber of the plasma processing apparatus 1, the substrate W is carried into the plasma processing space 10s of the plasma processing apparatus 1 and is disposed on the substrate support 11, and thereby the substrate W may be provided.

After the substrate W is provided to the center region 111a of the substrate support 11, the temperature of the substrate support 11 is adjusted to a set temperature by the temperature-controlled module. The set temperature may be, for example, a temperature of 70° C. or lower (for example, room temperature). Further, the set temperature may be, for example, 0° C. or lower, −10° C. or lower, −20° C. or lower, −30° C. or lower, −40° C. or lower, −50° C. or lower, −60° C. or lower, or −70° C. or lower. In an example, adjusting or maintaining the temperature of the substrate support 11 includes setting the temperature of the heat transfer fluid flowing through the flow path 1110a or the heater temperature to the set temperature, or setting a temperature different from the set temperature. Timing at which the heat transfer fluid starts to flow through the flow path 1110a may be before or after the substrate W is placed on the substrate support 11, or may be at the same time. Further, the temperature of the substrate support 11 may be adjusted to the set temperature before step ST11. That is, the substrate W may be provided to the substrate support 11 after the temperature of the substrate support 11 is adjusted to the set temperature.

Next, in step ST12, the silicon-containing film SF is etched using a plasma formed from the first processing gas. First, the first processing gas is supplied from the gas supply 20 to the plasma processing space 10s. The first processing gas may be selected such that the silicon-containing film SF can be etched with a sufficient selectivity with respect to the mask MK. The first processing gas may contain one or a plurality of gases of the same type as the third processing gas used in the etching of step ST3 which is described later. The first processing gas may contain a fluorine-containing gas. In an example, the fluorine-containing gas may be a hydrogen fluoride gas (HF gas). In addition, the first processing gas may further contain one or more gases selected from the group consisting of a phosphorus-containing gas, a carbon-containing gas, a halogen-containing gas other than fluorine, an inert gas, and a metal-containing gas such as tungsten.

During the processing in step ST12, the gas contained in the first processing gas and the flow rate (partial pressure) thereof may be changed or may not be changed. For example, when the silicon-containing film SF is formed of a stacked film consisting of different types of silicon-containing films, the configuration of the processing gas and the flow rate of each gas may depend on the progress of etching, that is, may be changed depending on the type of film to be etched. During the processing in step ST12, the temperature of the substrate support 11 may be maintained at the set temperature adjusted in step ST11. Further, the set temperature of the substrate support 11 may be changed according to the type of the first processing gas and/or the silicon-containing film and the like. For example, when the first processing gas contains the fluorine-containing gas, the set temperature of the substrate support 11 may be 0° C. or lower.

Next, in step ST12, the source RF signal is supplied to the lower electrode of the substrate support 11 and/or the upper electrode of the shower head 13. As a result, a RF electric field is generated between the shower head 13 and the substrate support 11, and plasma is generated from the processing gas in the plasma processing space 10s. A portion (portion exposed at the opening OP) of the silicon-containing film SF that is not covered by the mask MK is etched by the active species such as ions and radicals in plasma. Etching in step ST12 is continued until a depth of the recess portion RC becomes a given depth. The etching in step ST12 is ended at least before the underlying film UF is exposed.

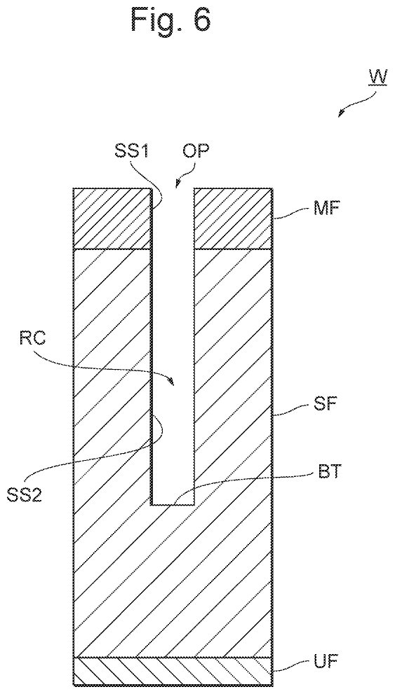

FIG. 6 is a diagram illustrating an example of a cross-sectional structure of the substrate W after the processing in step ST12. As illustrated in FIG. 6, by the etching in step ST12, an exposed portion of the silicon-containing film SF at the opening OP is etched in a depth direction (direction from top to bottom in FIG. 4) to form the recess portion RC.

In step ST12, the bias signal may be supplied to the lower electrode of the substrate support 11. The bias signal may be the bias RF signal supplied from the second RF generator 31b. In addition, the bias signal may be the bias DC signal supplied from the DC generator 32a. Both of the source RF signal and the bias signal may be the continuous wave or the pulse wave, and one may be the continuous wave and the other may be the pulse wave. When both the source RF signal and the bias signal are the pulse waves, cycles of both pulse waves may or may not be synchronized. A duty ratio of the pulse wave of the source RF signal and/or the bias signal may be appropriately set, and may be, for example, 1 to 80% and 5 to 50%. The duty ratio is a ratio occupied by a period in which power or a voltage level is high in the cycle of the pulse wave. In addition, when the bias DC signal is used as the bias signal, the pulse wave may have a rectangular shape, a trapezoidal shape, a triangular shape, or a waveform of a combination thereof. The polarity of the bias DC signal may be negative or positive as long as the potential of the substrate W is set so as to give a potential difference between plasma and the substrate W to draw ions.

In addition, in step ST12, the supply and stop of at least one of the source RF signal and the bias signal may be alternately repeated. For example, while the source RF signal is continuously supplied, the supply and stop of the bias signal may be alternately repeated. Further, for example, while the supply and stop of the source RF signal are alternately repeated, the bias signal may be continuously supplied. Further, for example, the supply and stop of both the source RF signal and the bias signal may be alternately repeated.

As described above, in step ST1, the substrate W including the silicon-containing film SF having the recess portion RC and the mask MK is prepared on the substrate support 11 of the plasma processing chamber 10. In the above-described example, the recess portion RC is formed after the substrate W is provided on the substrate support 11. However, after the recess portion RC is formed in the substrate W by an external device or chamber of the capacitively coupled plasma processing apparatus 1 illustrated in FIG. 2, the substrate W may be provided on the substrate support 11 of the capacitively coupled plasma processing apparatus 1 illustrated in FIG. 2, and thereby the substrate W may be prepared. The external device may be one of the substrate processing modules PM included in the substrate processing system PS.

### (Step ST2: Forming Carbon-Containing Film on Substrate)

In step ST2, the carbon-containing film CF is formed on the substrate W. Step ST2 includes step ST21 of transporting the substrate W to the plasma processing chamber 10 of the inductively coupled plasma processing apparatus 1 illustrated in FIG. 3, and step ST22 of forming the carbon-containing film on the substrate W in the plasma processing chamber 10. The plasma processing chamber 10 of the inductively coupled plasma processing apparatus 1 illustrated in FIG. 3 is an example of the first chamber. In step ST21, the substrate W may be transported via a transport chamber having a transport device. As an example, the transport chamber is a chamber included in the transport module TM. A pressure in the transport chamber may be lower than a pressure outside the transport chamber. The inside of the transport chamber may be maintained in a decompression atmosphere that is the same as or similar to that of the chamber used in step ST1 and/or the chamber used in step ST2.

In step ST21, the substrate W is transported to the plasma processing chamber 10 of the inductively coupled plasma processing apparatus 1 illustrated in FIG. 3, and disposed on the substrate support 11. The carbon-containing film CF is formed on the substrate W in step ST22. The formation of the carbon-containing film CF may be executed in various methods. As an example, a method using plasma CVD will be described below. First, the second processing gas containing the carbon-containing gas is supplied from the gas supply 20 to the plasma processing space 10s. The carbon-containing gas may be, for example, the hydrocarbon gas. In an example, the hydrocarbon gas is at least one gas selected from the group consisting of CH₄ gas, C₂H₂ gas, C₂H₄ gas, and C₃H₆ gas. In addition, as the carbon-containing gas, a gas containing fluorine such as CH₃F gas and C₄F₆ gas may also be used. In this case, conditions under which the deposition is dominant over the etching of the silicon-containing film SF are selected. The second processing gas may further contain the nitrogen-containing gas such as N₂ gas or NH₃ gas. The second processing gas may further contain the hydrogen-containing gas such as H₂ gas.

Next, the source RF signal is supplied to the antenna 14. As a result, plasma is generated from the second processing gas in the plasma processing space 10s. Then, the carbon or the active species containing carbon generated in plasma is adsorbed to the surface of the substrate W, and the carbon-containing film CF is formed on the surface of the substrate W.

In step ST2, the temperature of the substrate support 11 may be set to a higher temperature than the temperature of the substrate support 11 in step ST12 or step 3. The set temperature may be, for example, 0° C. or higher.

In addition, in step ST2, the plasma may be formed such that the incident of ions on the substrate W is suppressed. For example, the bias signal does not have to be supplied.

Further, in step ST2, in addition to the step of forming the plasma from the second processing gas described above, a step of forming plasma from a processing gas containing a nitrogen-containing gas such as N₂ gas or NH₃ gas may be included. As a result, excessive deposition of carbon in plasma on the substrate W and clogging of the opening OP may be suppressed. In step ST2, the step of forming the plasma from the second processing gas and the step of forming plasma from the processing gas containing the nitrogen-containing gas may be alternately repeated plural times. The processing gas containing the nitrogen-containing gas may further contain a hydrogen-containing gas such as H₂ gas.

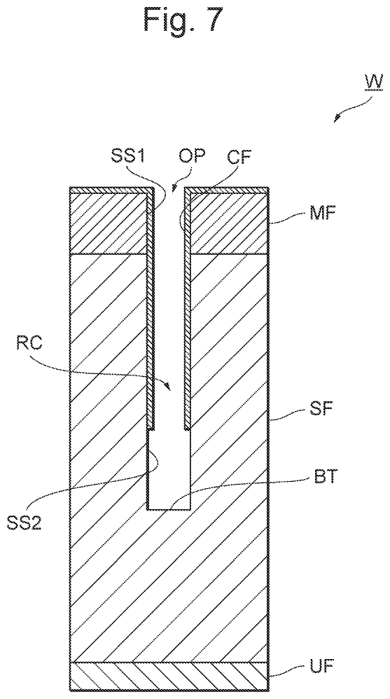

FIG. 7 is a diagram illustrating an example of a cross-sectional structure of the substrate W after the processing in step ST2. As illustrated in FIG. 7, the carbon-containing film CF is formed on the substrate W. The carbon-containing film CF is formed at least a part of the side wall SS2 of the silicon-containing film SF that defines the recess portion RC. The part of the side wall SS2 may be a part where active species (including those reflected on the side wall SS1 of the mask MK) in plasma incident on the opening OP collide frequently in the etching in step ST3. For example, the part of the side wall SS2 may be a portion of 10%, 20%, 30%, 40%, 50%, 60%, 70%, 80%, or 90% of the upper side of the side wall SS2 of the silicon-containing film in the depth direction. As illustrated in FIG. 7, the carbon-containing film CF may be formed over a part of the side wall SS2 of the silicon-containing film SF from the side wall SS1 which defines the upper surface of the mask MK and the opening OP. As will be described later, the carbon-containing film CF may function as a protective film against etching in the etching in step ST3.

The carbon-containing film CF may be formed by an ALD or a subconformal ALD instead of the plasma CVD.

The ALD includes a first step and a second step. First, in a first step, a precursor gas containing an organic compound is supplied to the substrate W. The organic compound may include, for example, at least one selected from the group consisting of epoxide, carboxylic acid, carboxylic acid halide, carboxylic anhydride, isocyanate, and phenols. By the first step, the precursor gas is adsorbed on the surfaces of the mask MK and the silicon-containing film SF. In the first step, plasma may be generated from the precursor gas.

Next, in a second step, a reaction gas is supplied to the substrate W. The reaction gas is a gas that reacts with the precursor gas adsorbed on the surface of the substrate W. The reaction gas may include at least one selected from the group consisting of an inorganic compound gas having an NH bond, an inert gas, a mixed gas of N₂ gas and H₂ gas, H₂O gas, and a mixed gas of H₂ gas and O₂ gas. The inorganic compound gas having the NH bond may be, for example, at least one gas of N₂H₂ gas and NH₃ gas. By the second step, the precursor gas and the reaction gas react with each other to form the carbon-containing film CF. In the second step, plasma may be generated from the reaction gas.

The inert gas or the like may be supplied to the substrate W between the first step and the second step, and/or after the second step. As a result, an excess of the precursor gas or the reaction gas is purged (purge step). In the ALD, a predetermined material adsorbs and reacts with a substance existing on the surface of the substrate W in a self-controlled manner to form the carbon-containing film CF. In the ALD, the conformal carbon-containing film CF is usually formed by providing a sufficient processing time.

The carbon-containing film CF may be formed by MLD. That is, the carbon-containing film CF may be formed by polymerizing an organic compound. The MLD includes a first step and a second step. First, in the first step, a first film formation gas is supplied to the substrate W. The first film formation gas contains a first organic compound. In the first step, the first film formation gas is adsorbed onto the surface of the substrate W. The surface may include a side wall SS1, a side wall SS2, and a bottom surface BT.

Next, in the second step, a second film formation gas is supplied to the substrate W. The second film formation gas contains a second organic compound. In the second step, the first organic compound adsorbed on the surface of the substrate W polymerizes with the second organic compound. Through this polymerization, the carbon-containing film CF is formed on the surface of the substrate W.

An inert gas or the like may be supplied to the substrate W between the first step and the second step and/or after the second step. Therefore, the first organic compound and/or the second organic compound excessively grown on the surface of the substrate W may be removed.

In one embodiment, the first organic compound may be a monofunctional isocyanate or a difunctional isocyanate, and the second organic compound may be a monofunctional amine or a difunctional amine. Moreover, in an embodiment, the organic compound obtained by polymerization (addition condensation) of an isocyanate and an amine may be a compound having a urea bond.

In an embodiment, the first organic compound may be a monofunctional isocyanate or a difunctional isocyanate, and the second organic compound may be a monofunctional compound having a hydroxyl group or a difunctional compound having a hydroxyl group. Moreover, in an embodiment, the organic compound obtained by polymerization (polyaddition) of an isocyanate and a compound having a hydroxyl group may be a compound having a urethane bond.

In an embodiment, the first organic compound may be a monofunctional carboxylic acid or a difunctional carboxylic acid, and the second organic compound may be a monofunctional amine or a difunctional amine. In an embodiment, the organic compound obtained by polymerization (polycondensation) of a carboxylic acid and an amine may be a compound having an amide bond. As an example, a compound with amide bonds may be a polyamide.

In an embodiment, the first organic compound may be a monofunctional carboxylic acid or a difunctional carboxylic acid, and the second organic compound may be a monofunctional compound having a hydroxyl group or a difunctional compound having a hydroxyl group. In an embodiment, the organic compound obtained by polymerization (polycondensation) of a carboxylic acid and a compound having a hydroxyl group may be a compound having an ester bond. As an example, a compound with polyester bonds may be an ester.

In an embodiment, the first organic compound may be a carboxylic anhydride and the second organic compound may be an amine. In an embodiment, the organic compound obtained by polymerizing a carboxylic anhydride and an amine may be an imide compound.

In an embodiment, the first organic compound may be bisphenol A and the second organic compound may be diphenyl carbonate.

In an embodiment, the first organic compound may be bisphenol A and the second organic compound may be epichlorohydrin.

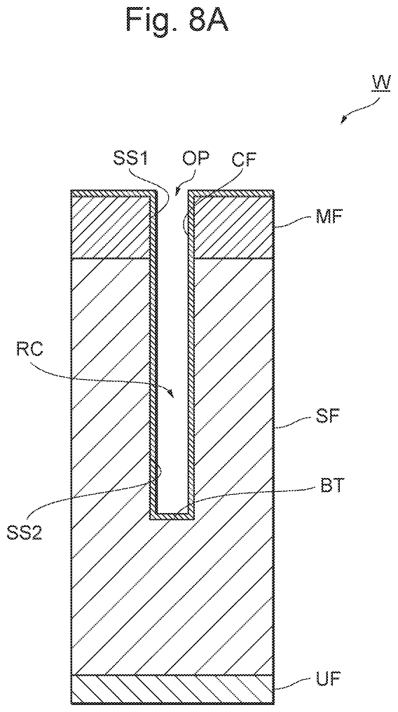

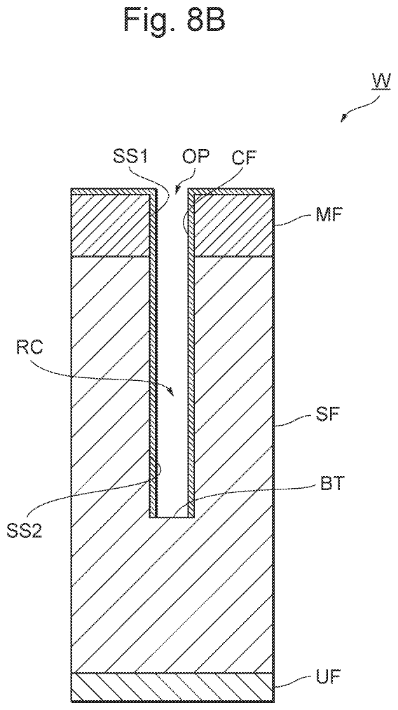

FIG. 8A is a diagram illustrating another example of the cross-sectional structure of the substrate W after the processing in step ST2. FIG. 8A is an example of a case where the conformal carbon-containing film CF is formed by the ALD or the MLD. As illustrated in FIG. 8A, the carbon-containing film CF is evenly formed on all of the side wall SS1 defining the upper surface of the mask MK and the opening OP, the side wall SS2 defining the recess portion RC of the silicon-containing film SF, and the bottom surface BT.

In a case where the conformal carbon-containing film CF is formed in step ST2, step ST2 may further include a step (breakthrough step) of removing the carbon-containing film formed on the bottom surface BT of the recess portion RC. The breakthrough step may be performed by, for example, forming the plasma from the processing gas containing N₂ gas and H₂ gas. At this time, the bias signal may be supplied to the substrate support 11.

FIG. 8B is a diagram illustrating an example of a cross-sectional structure of the substrate W after the breakthrough step. As illustrated in FIG. 8B, the carbon-containing film CF formed on the bottom surface BT of the silicon-containing film SF is removed, and the bottom surface, that is, a portion to be etched in step ST3 is exposed to the recess portion RC.

The sub-conformal ALD is a method for setting processing conditions such that self-controlled adsorption or reaction is not completed on the surface of the substrate W. The sub-conformal ALD has at least two processing modes as follows.

(i) After the precursor gas is adsorbed on the entire surface of the substrate W, the reaction gas is controlled not to spread over the precursor gas adsorbed on the entire surface of the substrate W.

(ii) After the precursor gas is adsorbed only on a part of the surface of the substrate W, the reaction gas is reacted only with a precursor gas adsorbed on the surface of the substrate W.

According to the sub-conformal ALD, the carbon-containing film CF whose film thickness decreases along the depth direction of the recess portion RC is formed. When the carbon-containing film is also formed on the bottom surface BT of the silicon-containing film SF, the breakthrough step described above may be executed.

In step ST22, the carbon-containing film CF may form the plasma from a processing gas containing a gas of a low vapor pressure material, and deposit a fluidized film generated from the low vapor pressure material in the recess portion RC by this plasma to be formed. In an example, the gas of the low vapor pressure material includes at least one gas selected from the group consisting of C₃F₆ gas, C₄F₆ gas, C₄F₈ gas, isopropyl alcohol (IPA) gas, C₃H₂F₄ gas, and C₄H₂F₆ gas. The gas of the low vapor pressure material may be a gas having a vapor pressure at the same temperature as or higher than a temperature indicated by a temperature-vapor pressure curve of C₄F₈. In this case, the pressure in the plasma processing space 10s may be, for example, 50 mT (6.7 Pa) or more, and the temperature of the substrate support 11 may be set to 0° C. or less.

In addition to the above, the carbon-containing film CF may be formed by various methods such as thermal CVD.

### (Step ST3: Etching of Substrate)

In step ST3, the silicon-containing film SF is etched. Step ST3 includes step ST31 of transporting the substrate W to the plasma processing chamber 10 of the capacitively coupled plasma processing apparatus 1 illustrated in FIG. 2 and step ST32 of etching the substrate Win the plasma processing chamber 10. The plasma processing chamber 10 of the capacitively coupled plasma processing apparatus 1 illustrated in FIG. 2 is an example of the second chamber. In step ST31, the substrate W may be transported via a transport chamber having a transport device in the same manner as in step ST21. As an example, the transport chamber is a chamber included in the transport module TM. A pressure in the transport chamber may be lower than a pressure outside the transport chamber. The inside of the transport chamber may be maintained in the same or similar decompression atmosphere as the inside of the chamber used in step ST1 and/or ST3 and/or the chamber used in step ST2. In addition, step ST3 may be executed by the inductively coupled plasma processing apparatus 1 illustrated in FIG. 3.

In step ST31, the substrate W is transported to the plasma processing chamber 10 of the capacitively coupled plasma processing apparatus 1 illustrated in FIG. 2, and disposed on the substrate support 11. The silicon-containing film SF is etched in step ST32. First, the third processing gas containing the HF gas is supplied from the gas supply 20 to the plasma processing space 10s. During the processing in step ST3, the gas included in the third processing gas and the flow rate (partial pressure) thereof may or may not be changed. For example, in a case where the silicon-containing film SF is formed of a stacked film consisting of different types of silicon-containing films, the configuration of the third processing gas and the flow rate of each gas may be changed according to the progress of etching, that is, the type of film to be etched. In step ST3, the temperature of the substrate support 11 may be appropriately set according to a processing gas, the type of the silicon-containing film, and the like. For example, when the processing gas includes the fluorine-containing gas, the set temperature of the substrate support 11 may be 0° C. or lower.

Next, the source RF signal is supplied to the lower electrode of the substrate support 11 and/or the upper electrode of the shower head 13. As a result, a RF electric field is generated between the shower head 13 and the substrate support 11, and plasma is generated from the third processing gas in the plasma processing space 10s.

In step ST3, the bias signal may be supplied to the lower electrode of the substrate support 11. In this case, a bias potential is generated between the plasma and the substrate W, and active species such as ions and radicals in the plasma are attracted to the substrate W, and etching of the silicon-containing film SF may be promoted. The bias signal may be the bias RF signal supplied from the second RF generator 31b. In addition, the bias signal may be the bias DC signal supplied from the DC generator 32a.

Both the source RF signal and the bias signal may be the continuous wave or the pulse wave, one may be the continuous wave, and the other may be the pulse wave. When both the source RF signal and the bias signal are the pulse waves, cycles of both pulse waves may or may not be synchronized. A duty ratio of the pulse wave of the source RF signal and/or the bias signal may be appropriately set, and may be, for example, 1 to 80% and 5 to 50%. In addition, when the bias DC signal is used as the bias signal, the pulse wave may have a rectangular shape, a trapezoidal shape, a triangular shape, or a waveform of a combination thereof. The polarity of the bias DC signal may be negative or positive as long as the potential of the substrate W is set so as to give a potential difference between plasma and the substrate W to draw ions.

In step ST3, supply and stop of at least one of the source RF signal and the bias signal may be alternately repeated. For example, while the source RF signal is continuously supplied, the supply and stop of the bias signal may be alternately repeated. Further, for example, while the supply and stop of the source RF signal are alternately repeated, the bias signal may be continuously supplied. Further, for example, the supply and stop of both the source RF signal and the bias signal may be alternately repeated.

The fluorine-containing gas included in the third processing gas may be, for example, a hydrofluorocarbon gas in addition to the HF gas. The hydrofluorocarbon gas may have 2 or more carbon atoms, 3 or more carbon atoms, or 4 or more carbon atoms. In an example, the hydrofluorocarbon gas is at least one selected from the group consisting of CH₂F₂ gas, C₃H₂F₄ gas, C₃H₂F₆ gas, C₃H₃F₅ gas, C₄H₂F₆ gas, C₄H₅F₅ gas, C₄H₂F₈ gas, C₅H₂F₆ gas, C₅H₂F₁₀ gas, and C₅H₃F₇ gas. In an example, the hydrofluorocarbon gas is at least one selected from the group consisting of CH₂F₂ gas, C₃H₂F₄ gas, C₃H₂F₆ gas, and C₄H₂F₆ gas.

The fluorine-containing gas may be, for example, a mixed gas containing a hydrogen source and a fluorine source. The hydrogen source may be, for example, at least one selected from the group consisting of H₂ gas, NH₃ gas, H₂O gas, H₂O₂ gas, and hydrocarbon gas (CH₄ gas, C₃H₆ gas, and the like). The fluorine source may be, for example, a fluorine-containing gas that does not include carbon, such as NF₃ gas, SF₆ gas, WF₆ gas, or XeF₂ gas. In addition, the fluorine source may be a fluorine-containing gas containing carbon, such as fluorocarbon gas and hydrofluorocarbon gas. In an example, the fluorocarbon gases may be at least one selected from the group consisting of CF₄ gas, C₂F₂ gas, C₂F₄ gas, C₃F₆ gas, C₃F₈ gas, C₄F₆ gas, C₄F₈ gas, and C₅F₈ gas. In an example, the hydrofluorocarbon gas may be at least one selected from the group consisting of CHF₃ gas, CH₂F₂ gas, CH₃F gas, C₂HF₅ gas, and a hydrofluorocarbon gas containing three or more of C (C₃H₂F₄ gas, C₃H₂F₆ gas, C₄H₂F₆ gas, and the like).

When the fluorine-containing gas is the HF gas, the HF gas may have the largest flow rate (partial pressure) in the third processing gas (in a case where the third processing gas includes the inert gas, all gases except the inert gas). In an example, the flow rate of the HF gas may be 50 vol % or more, 60 vol % or more, 70 vol % or more, 80 vol % or more, 90 vol % or more, or 95 vol % or more with respect to the total flow rate of the third processing gas (flow rate of all gases except the inert gas in a case where the third processing gas includes the inert gas). The flow rate of the HF gas may be less than 100 vol %, 99.5 vol % or less, 98 vol % or less, or 96 vol % or less with respect to the total flow rate of the third processing gas. In an example, the flow rate of the HF gas is adjusted to 70 vol % or more and 96 vol % or less with respect to the total flow rate of the third processing gas.

In addition, the third processing gas may further include a tungsten-containing gas. The tungsten-containing gas included in the third processing gas may be, for example, a gas containing tungsten and halogen. In an example, the tungsten-containing gas is a WFₓCl_{y} gas (x and y are integers of 0 or more and 6 or less, and a sum of x and y is 2 or more and 6 or less). Specifically, the tungsten-containing gas may be a gas containing tungsten and fluorine such as tungsten difluoride (WF₂) gas, tungsten tetrafluoride (WF₄) gas, tungsten pentafluoride (WF₅) gas, and tungsten hexafluoride (WF₆) gas, and a gas containing tungsten and chlorine such as tungsten dichloride (WCl₂) gas, tungsten tetrachloride (WCl₄) gas, tungsten pentachloride (WCl₅) gas, and tungsten hexachloride (WCl₆) gas. Among these, at least one of WF₆ gas and WCl₆ gas may be used. The flow rate of the tungsten-containing gas may be 5 vol % or less of the total flow rate of the third processing gas. The third processing gas may include at least one of a titanium-containing gas, a molybdenum-containing gas, and a ruthenium-containing gas in place of or in addition to the tungsten-containing gas.

The third processing gas may further include a phosphorus-containing gas. The phosphorus-containing gas is a gas containing a phosphorus-containing molecule. The phosphorus-containing molecule may be an oxide such as tetraphosphorus decaoxide (P₄O₁₀), tetraphosphorus octoxide (P₄O₈), and tetraphosphorus hexaoxide (P₄O₆). Tetraphosphorus decaoxide is sometimes referred to as phosphorus pentoxide (P₂O₅). The phosphorus-containing molecule may be halides (phosphorous halides) such as phosphorus trifluoride (PF₃), phosphorus pentafluoride (PF₅), phosphorus trichloride (PCl₃), phosphorus pentachloride (PCl₅), phosphorus tribromide (PBr₃), phosphorus pentabromide (PBr₅), and phosphorus iodide (PI₃). That is, the phosphorus-containing molecule may include fluorine as a halogen element such as phosphorus fluoride. Alternatively, the phosphorus-containing molecule may include a halogen element other than fluorine as the halogen element. The phosphorus-containing molecule may be a phosphoryl halide such as phosphoryl fluoride (POF₃), phosphoryl chloride (POCl₃), and phosphoryl bromide (POBr₃). The phosphorus-containing molecule may be phosphine (PH₃), calcium phosphate (Ca₃P₂ and the like), phosphoric acid (H₃PO₄), sodium phosphate (Na₃PO₄), hexafluorophosphoric acid (HPF₆), and the like. The phosphorus-containing molecule may be fluorophosphines (H_{g}PFₕ). Here, a sum of g and h is 3 or 5. As the fluorophosphines, HPF₂ and H₂PF₃ are illustrated. The processing gas may include one or more phosphorus-containing molecules among the above-described phosphorus-containing molecules as at least one phosphorus-containing molecule. For example, the second processing gas may include at least one of PF₃, PCl₃, PF₅, PCl₅, POCl₃, PH₃, PBr₃, or PBr₅ as at least one phosphorus-containing molecule. In a case where each phosphorus-containing molecule included in the third processing gas is a liquid or a solid, each phosphorus-containing molecule may be vaporized by heating or the like and supplied into the plasma processing space 10s.

The phosphorus-containing gas may be a PCLₐF_{b} (a is an integer of 1 or more, b is an integer of 0 or more, and a+b is an integer of 5 or less) gas or PC c H d F e (d and e are each an integer of 1 or more and 5 or less, and c is an integer of 0 or more and 9 or less) gas.

The PCLₐF_{b} gas may be, for example, at least one gas selected from the group consisting of PClF₂ gas, PCl₂F gas, and PCl₂F₃ gas.

The PC_{c}H_{d}Fₑ gas may be, for example, at least one gas selected from the group consisting of PF₂CH₃ gas, PF(CH₃)₂ gas, PH₂CF₃ gas, PH(CF₃)₂ gas, PCH₃(CF₃)₂ gas, PH₂F gas, and PF₃(CH₃)₂ gas.

The phosphorus-containing gas may be a PCL_{c}F_{d}CₑH_{f} gas (where each of c, d, e, and f is an integer of 1 or more). In addition, the phosphorus-containing gas may be a gas containing phosphorus (P), halogen (for example, Cl, Br, or I) other than fluorine (F) in the molecular structure, a gas containing phosphorus (P), fluorine (F), carbon (C), and hydrogen (H) in the molecular structure, or a gas containing phosphorus (P), fluorine (F), and hydrogen (H) in the molecular structure.

The phosphorus-containing gas may be used as the phosphine-based gas. Examples of the phosphine-based gas include phosphine (PH 3), a compound in which at least one hydrogen atom of phosphine is replaced with an appropriate substituent, and a phosphinic acid derivative.

The substituent that replaces the hydrogen atom of the phosphine is not particularly limited, and is, for example, a halogen atom such as a fluorine atom or a chlorine atom; an alkyl group such as a methyl group, an ethyl group, or a propyl group; a hydroxyalkyl group such as a hydroxymethyl group, a hydroxyethyl group, or a hydroxypropyl group, or the like, and is, as an example, a chlorine atom, a methyl group, and a hydroxymethyl group.

Examples of the phosphinic acid derivative include phosphinic acid (H₃O₂P), alkylphosphinic acid (PHO(OH)R), and dialkylphosphinic acid (PO(OH)R₂).

For example, the phosphine-based gas may be at least one gas selected from the group consisting of dichloro(methyl)phosphine (PCH₃Cl₂) gas, chloro(dimethyl)phosphine (P(CH₃)₂Cl) gas, dichloro(hydroxylmethyl)phosphine (P(HOCH₂)Cl₂) gas, chloro(dihydroxylmethyl) phosphine (P(HOCH₂)₂Cl) gas, dimethyl(hydroxylmethyl)phosphine (P(HOCH₂)(CH₃)₂) gas, methyl(dihydroxylmethyl)phosphine (P(HOCH₂)₂(CH₃)) gas, tris(hydroxylmethyl)phosphine (P(HOCH₂)₃) gas, phosphinic acid (H₃O₂P) gas, methylphosphinic acid (PHO(OH)(CH₃) gas, and dimethylphosphinic acid (PO(OH)(CH₃)₂) gas.

The flow rate of the phosphorus-containing gas may be 20 vol % or less, 10 vol % or less, and 5 vol % or less of the total flow rate of the third processing gas.

The third processing gas may further contain a carbon-containing gas. The carbon-containing gas may be, for example, either or both of a fluorocarbon gas and a hydrofluorocarbon gas. In an example, the fluorocarbon gas may be at least one selected from the group consisting of CF₄ gas, C₂F₂ gas, C₂F₄ gas, C₃F₆ gas, C₃F₈ gas, C₄F₆ gas, C₄F₈ gas, and C₅F₈ gas. In an example, the hydrofluorocarbon gas may be at least one selected from the group consisting of CHF₃ gas, CH₂F₂ gas, CH₃F gas, C₂HF₅ gas, C₂H₂F₄ gas, C₂H₃F₃ gas, C₂H₄F₂ gas, C₃HF₇ gas, C₃H₂F₂ gas, C₃H₂F₄ gas, C₃H₂F₆ gas, C₃H₃F₅ gas, C₄H₂F₆ gas, C₄H₅F₅ gas, C₄H₂F₈ gas, C₅H₂F₆ gas, C₅H₂F₁₀ gas, and C₅H₃F₇ gas. In addition, the carbon-containing gas may be a linear one having an unsaturated bond. The linear carbon-containing gas having the unsaturated bond may be, for example, at least one selected from the group consisting of hexafluoropropene (C₃F₆) gas, octafluoro-1-butene, octafluoro-2-butene (C₄F₈) gas, 1,3,3,3-tetrafluoropropene (C₃H₂F₄) gas, trans-1,1,1,4,4,4-hexafluoro-2-butene (C₄H₂F₆) gas, pentafluoroethyl trifluorovinyl ether (C₄F₈O) gas, CF₃COF gas (1,2,2,2-tetrafluoroethane-1-one), difluoroacetic acid fluoride (CHF₂COF) gas, and carbonyl fluoride (COF₂) gas.

The third processing gas may further include an oxygen-containing gas. The oxygen-containing gas may be, for example, at least one gas selected from the group consisting of O₂, CO, CO₂, H₂O, and H₂O₂. In an example, the oxygen-containing gas may be an oxygen-containing gas other than H₂O, for example, at least one gas selected from the group consisting of O₂, CO, CO₂, and H₂O₂. The flow rate of the oxygen-containing gas may be adjusted according to the flow rate of the carbon-containing gas.

The third processing gas may further include a halogen-containing gas other than fluorine. The halogen-containing gas other than fluorine may be a chlorine-containing gas, a bromine-containing gas, and/or an iodine-containing gas. In an example, the chlorine-containing gas may be at least one gas selected from the group consisting of Cl₂, SiCl₂, SlCl₄, CCl₄, SiH₂Cl₂, Si₂Cl₆, CHCl₃, SO₂Cl₂, BCl₃, PCl₃, PCl₅, and POCl₃. In an example, the bromine-containing gas may be at least one gas selected from the group consisting of Br₂, HBr, CBr₂F₂, C₂F₅Br, PBr₃, FBr₅, POBr₃, and BBr₃. In an example, the iodine-containing gas may be at least one gas selected from the group consisting of HI, CF₃I, C₂F₅I, C₃F₇I, IF₅, IF₇, I₂, and PI₃. In an example, the halogen-containing gas other than fluorine may be at least one selected from the group consisting of Cl₂ gas, Br₂ gas and HBr gas. In an example, the halogen-containing gas other than fluorine is Cl₂ gas or HBr gas.

The third processing gas may further include an inert gas. In an example, the inert gas may be a noble gas such as Ar gas, He gas, and Kr gas, or nitrogen gas.

In an embodiment, step ST32 may include a plurality of steps of exposing the substrate W to different types of plasma. In an embodiment, step ST32 may include a step of forming the plasma from a fourth processing gas, a step of forming plasma from a fifth processing gas, and a step of forming plasma from a sixth processing gas. The steps of forming plasma from the fourth processing gas, forming plasma from the fifth processing gas, and forming plasma from the sixth processing gas may be repeatedly performed.

In the step of forming plasma from the fourth processing gas, the fourth processing gas may contain hydrogen fluoride gas. Further, the step of forming plasma from the fourth processing gas may be performed under the same conditions as those of step ST32. In an embodiment, the fourth processing gas may contain, in addition to hydrogen fluoride gas, one or more of the gases that may be contained in the third processing gas. The silicon-containing film SF may be etched at the bottom surface BT of the recess portion RC (see FIG. 8B) by exposing the substrate W to the plasma formed from the fourth processing gas.

In the step of forming plasma from the fifth processing gas, the fifth processing gas may contain a fluorocarbon gas and/or a hydrofluorocarbon gas. Further, the step of forming the plasma from the fourth processing gas may be performed under the same conditions as those of step ST22. As an example, the fifth processing gas may include CH₄. Further, in an embodiment, the fifth processing gas may contain, in addition to the fluorocarbon gas and/or the hydrofluorocarbon gas, one or more of the gases that may be contained in the second processing gas. By exposing the substrate W to plasma formed from the fifth processing gas, a carbon-containing film may be formed on the surface of the portion etched in the step of forming the plasma from the fourth processing gas. As an example, the thickness of the carbon-containing film may be 1 to 10 nm. In an embodiment, the carbon-containing film may be formed by the ALD or the MLD.

In the step of forming plasma from the sixth processing gas, the sixth processing gas may contain a hydrogen-containing gas. As an example, the hydrogen-containing gas may contain H₂. As an example, the flow rate ratio of H₂ to the total flow rate of the sixth processing gas may be 50% or more. As an example, the time period for exposing the substrate W to the plasma formed from the sixth processing gas may be 1 second to 30 seconds. In the step of forming the plasma from the sixth processing gas, the pressure within the plasma processing chamber 10 may be 1 mTorr to 1,000 mTorr. Fluorine atoms contained in the carbon-containing film formed from the fifth processing gas may be replaced with hydrogen atoms by exposing the substrate W to the plasma formed from the sixth processing gas.

In step ST32, by repeatedly performing the step of forming the plasma from the fourth processing gas, the step of forming plasma from the fifth processing gas, and the step of forming plasma from the sixth processing gas, the recess portion RC can be formed deeper in the silicon-containing film SF while protecting the side wall SS2 of the silicon-containing film SF. Therefore, shape abnormality of the recess portion RC formed in the silicon-containing film SF can be suppressed.

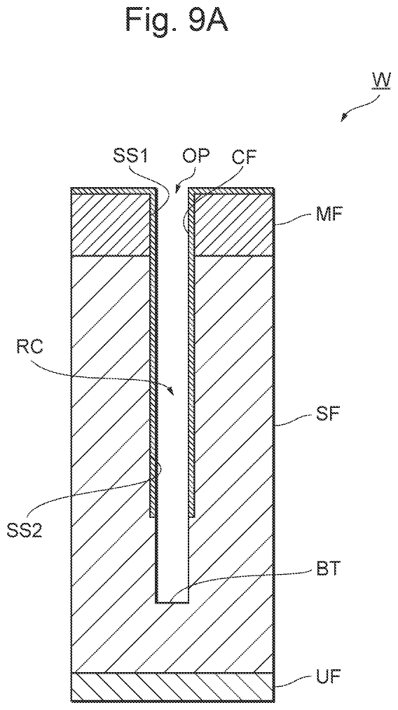

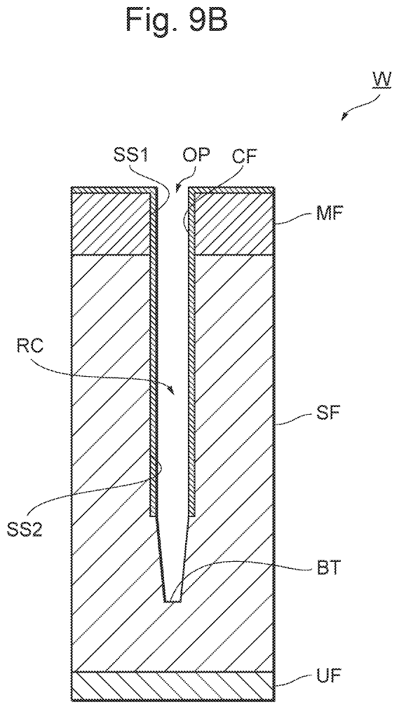

FIG. 9A is a diagram illustrating an example of a cross-sectional structure of the substrate W during the processing in step ST3. As illustrated in FIG. 9A, a portion of the silicon-containing film SF (portion exposed at the opening OP), which is not covered by the mask MK, is etched in the depth direction by the active species of fluorine in the plasma. Here, at least a part of the carbon-containing film CF may function as a protective film that protects the side wall SS2 of the silicon-containing film SF that defines the recess portion RC. Therefore, the removal of the side wall SS2 of the silicon-containing film SF by etching during the processing of step ST3 is suppressed.

Step ST3 may include a step of improving the shape of the recess portion RC. As an example, as illustrated in FIG. 9B, a dimension of the recess portion RC in a width direction in the portion etched in step ST3 may be narrower than a dimension of the recess portion RC in the width direction in the portion protected by the carbon-containing film CF. In this case, step ST3 may further include a step of enlarging the dimensions of the recess portion RC in the portion etched in step ST3. Therefore, for example, even if the recess portion RC formed in step ST3 has a tapered shape as illustrated in FIG. 9B, the cross-sectional shape of the recess portion RC can be made closer to a vertical shape as illustrated in FIG. 9A. In an embodiment, the step of enlarging the dimensions of the recess portion RC may be performed by changing the parameters of step ST3. As an example, the parameter change may be to reduce the pressure within the plasma processing chamber 10 and/or to reduce the flow rate ratio of hydrogen fluoride gas to the total flow rate of processing gases.

As described above, in the present processing method, in step ST3, the etching of the side wall SS2 of the silicon-containing film SF in the lateral direction can be suppressed while etching the silicon-containing film SF in the depth direction. As a result, the present processing method can suppress the occurrence of shape abnormality due to etching such as bowing.

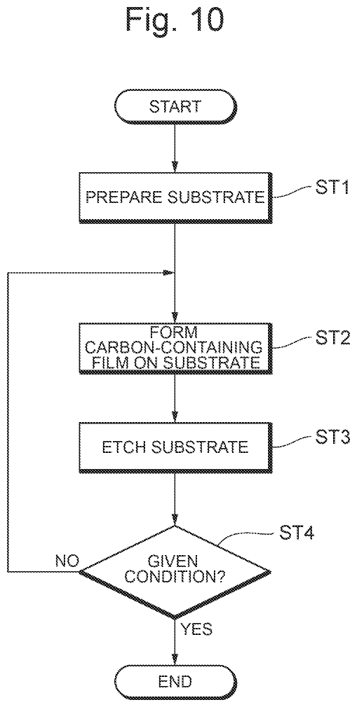

FIG. 10 is a flowchart illustrating another example of the present processing method. As illustrated in FIG. 10, in the present example, after step ST3, it is determined whether a given condition is satisfied, and step ST2 and step ST3 are repeated until it is determined that the given condition is satisfied. Except for this point, the present example is the same as the flowchart illustrated in FIG. 2.

The given condition in step ST4 may be appropriately determined. For example, the given condition may be a condition regarding the number of cycles in a case where step ST2 and step ST3 are set to one cycle. That is, it may be determined whether the number of cycles has reached the preset number of repetitions (for example, 10, 20, 30, 50, or the like), and step ST2 and step S3 may be repeated until the preset number of repetitions is reached. The number of repetitions may be set based on the film thickness (depth to be etched) of the silicon-containing film SF.

For example, the given condition may be a condition regarding the dimension of the recess portion RC after the processing in step ST3. That is, after step ST3, it may be determined whether the depth of the recess portion RC or the width of the bottom portion has reached a given value or range, and the cycle of step ST2 and step ST3 may be repeated until the given value or range is reached. The dimension of the recess portion RC may be measured by an optical measuring device. In a case where the present processing method processes a plurality of substrates W as one unit (hereinafter, referred to as “lot”), in only one or the plurality of substrates W included in the lot, the repetition of the cycle may be determined based on the dimensions of the processed recess portion RC. The number of cycles repeated at this time may be stored and used as the given condition for other substrates included in the lot. That is, for the other substrates, it is determined whether the number of stored cycles has been reached, and if the number of stored cycles has not been reached, step ST2 and step ST3 may be repeated.

### EXAMPLES

Next, examples of the present processing method will be described. The present invention is not limited in any way by following examples.

### Example 1

In Example 1, using the same substrate Was the substrate W illustrated in FIG. 5, the present processing method was executed according to the flowchart illustrated in FIG. 4, and the recess portion RC was formed in the silicon-containing film SF. The processing gas used in step ST12 and the flow rate thereof are the same as the processing gas used in step ST32 and the flow rate thereof.
a) Step ST12
Apparatus: capacitively coupled plasma processing apparatus (FIG. 2)
Processing gas: HF, hydrofluorocarbon, phosphorus-containing gas, halogen-containing gas
Set temperature of substrate support: −70° C.
b) Step ST22
Apparatus: inductively coupled plasma processing apparatus (FIG. 3)
Processing gas: hydrocarbon, hydrogen-containing gas, nitrogen-containing gas
c) Step ST32
Apparatus: capacitively coupled plasma processing apparatus (FIG. 2)
Processing gas: HF, hydrofluorocarbon, phosphorus-containing gas, halogen-containing gas
Set temperature of substrate support: −70° C.

### Reference Example 1

In Reference Example 1, the recess portion RC was formed in the silicon-containing film SF by using the same substrate W as in Example 1 and the same capacitively coupled plasma processing apparatus. In addition, the processing gas used in Reference Example 1 and the flow rate thereof are the same as the processing gas used in steps ST12 and ST32 of Example 1 and the flow rate thereof. In addition, the processing time of Reference Example 1 is the same as the total of the processing time of step ST12 and the processing time of step ST32 in Example 1.
Apparatus: capacitively coupled plasma processing apparatus (FIG. 2)
Processing gas: HF, hydrofluorocarbon, phosphorus-containing gas, halogen-containing gas
Set temperature of substrate support: −70° C.

After the end of step ST12 and the end of step ST32 of Example 1, and after the end of Reference Example 1, the maximum value of a critical dimension (CD) of the recess portion RC in the depth direction was measured.

In Example 1, a large difference was not seen between a maximum value of the CD after the end of step ST32 and a maximum value of the CD of the recess portion RC after the end of step ST12, and the occurrence of bowing was limited. On the other hand, the maximum value of the CD after the end of Reference Example 1 was about 1.2 times the maximum value of the CD after the end of step ST32 of Example 1, and the occurrence of bowing was remarkable. As described above, in Example 1, the bowing of the recess portion RC could be significantly suppressed as compared with that of Reference Example 1.

According to one exemplary embodiment of the present disclosure, it is possible to provide a technology for suppressing a shape abnormality in etching.

The embodiments of the present disclosure further include the following aspects.

### (Addendum 1)

A plasma processing system including
a first processing chamber having a first substrate support,
a second processing chamber that has a second substrate support and is different from the first processing chamber,
a transport chamber that is connected to the first processing chamber and the second processing chamber, and has a transport device, and
a controller,
in which the controller executes
(a) processing of disposing a substrate including a silicon-containing film having a recess portion and a mask on the silicon-containing film on the first substrate support of the first processing chamber, in which the mask has an opening that exposes the recess portion,
(b) processing of forming a carbon-containing film on a side wall of the silicon-containing film defining the recess portion in the first processing chamber,
(c) processing of transporting the substrate from the first processing chamber to the second processing chamber via the transport chamber and disposing the substrate on the second substrate support, and
(d) processing of etching a bottom portion of the recess portion where the carbon-containing film is formed by using a plasma formed from a first processing gas containing a hydrogen fluoride gas in the second processing chamber.

### (Addendum 2)

The plasma processing system according to addendum 1, in which the controller executes processing of repeating a cycle including (a), (b), (c), and (d) a plurality of times.

### (Addendum 3)

The plasma processing system according to addendum 1 or 2, in which at least in (c), the controller controls a pressure in the transport chamber so that the pressure in the transport chamber is lower than a pressure in the first processing chamber and a pressure in the second processing chamber.

### (Addendum 4)

The plasma processing system according to addendum 1 or 2, in which the controller executes processing of forming the recess portion on the silicon-containing film and preparing the substrate including the silicon-containing film having the recess portion by etching using a plasma formed from a second processing gas containing a fluorine-containing gas in the second processing chamber or in a third processing chamber different from the second processing chamber before (a).

### (Addendum 5)

The plasma processing system according to any one of addendums 1 to 3, in which a temperature of the first substrate support in the processing of (b) is higher than a temperature of the second substrate support in the processing of (c).

### (Addendum 6)

The plasma processing system according to any one of addendums 1 to 5, in which the controller executes processing of forming the carbon-containing film with a third processing gas containing a carbon-containing gas in (b).

### (Addendum 7)

The plasma processing system according to addendum 6, in which the carbon-containing gas is a hydrocarbon gas.

### (Addendum 8)

The plasma processing system according to addendum 6, in which the third processing gas further contains a nitrogen-containing gas.

### (Addendum 9)

The plasma processing system according to addendum 1, in which in (b), the controller executes processing including
(b11) a step of supplying a precursor gas to the substrate and adsorbing the precursor gas to the side wall, and
(b12) a step of supplying a reaction gas to the substrate and forming the carbon-containing film by a reaction between the precursor gas and the reaction gas.
   (Addendum 10) The plasma processing system according to addendum 1, in which (b) includes
(b1) a step of supplying a first film formation gas containing a first organic compound into the first processing chamber, and
(b2) a step of supplying a second film formation gas containing a second organic compound different from the first organic compound into the first processing chamber.

### (Addendum 11)

The plasma processing system according to addendum 10, in which (b2) forms the carbon-containing film by a reaction including polymerization of the first organic compound and the second organic compound.

### (Addendum 12)

The plasma processing system according to addendum 1, in which (d) further includes processing of enlarging a dimension of the portion that is etched in (d) in the recess portion.

### (Addendum 13)

The plasma processing system according to any one of addendums 1 to 12, in which the first processing gas further contains a phosphorus-containing gas.

### (Addendum 14)

The plasma processing system according to any one of addendums 1 to 13, in which the first processing gas further contains at least one gas selected from the group consisting of a carbon-containing gas, a halogen-containing gas, and a metal-containing gas.

### (Addendum 15)

The plasma processing system according to addendum 14, in which the processing of (d) is executed at a temperature of the second substrate support which is 0° C. or lower.

### (Addendum 16)

The plasma processing system according to any one of addendums 1 to 15, in which the first processing chamber is coupled to an inductively coupled plasma generator,
the second processing chamber is coupled to a capacitively coupled plasma generator, and
in the processing of (b), the controller executes processing of forming a plasma by the inductively coupled plasma generator to form the carbon-containing film, and in the processing of (d), the controller executes processing of forming a plasma by the capacitively coupled plasma generator to etch the silicon-containing film.

### (Addendum 17)

The plasma processing system according to any one of addendums 1 to 16, in which the silicon-containing film is a silicon oxide film, a silicon nitride film, a polycrystalline silicon film, or a stacked film including two or more of these.

### (Addendum 18)

The plasma processing system according to any one of addendums 1 to 17, in which the mask is a carbon-containing film or a metal-containing film.

### (Addendum 19)

A plasma processing system including
a first processing chamber having a first substrate support,
a second processing chamber that has a second substrate support and is different from the first processing chamber,
a transport chamber that is connected to the first processing chamber and the second processing chamber, and has a transport device,
a controller,
in which the controller executes
(a) processing of disposing a substrate including a silicon-containing film having a recess portion and a mask on the silicon-containing film on the first substrate support of the first processing chamber, in which the mask has an opening that exposes the recess portion,
(b) processing of forming a carbon-containing film on a side wall of the silicon-containing film defining the recess portion in the first processing chamber,
(c) processing of transporting the substrate from the first processing chamber to the second processing chamber via the transport chamber and disposing the substrate on the second substrate support, and
(d) processing of etching a bottom portion of the recess portion where the carbon-containing film is formed in the second processing chamber, and
the processing of (d) executes processing of repeating a cycle including
(d1) a step of exposing the substrate to a plasma formed from a fourth processing gas containing a hydrogen fluoride gas,
(d2) a step of exposing the substrate to a plasma formed from a fifth processing gas containing a fluorocarbon gas and/or a hydrofluorocarbon gas, and
(d3) a step of exposing the substrate to a plasma formed from a sixth processing gas containing a hydrogen-containing gas.

### (Addendum 20)

A plasma processing apparatus including
a chamber,
a substrate support disposed in the chamber,
a plasma generator, and
a controller,
in which the controller executes
(a) processing of disposing a substrate including a silicon-containing film having a recess portion and a mask, which has an opening exposing the recess portion, on the silicon-containing film and having an opening to expose the recess portion in the substrate support,
(b) processing of forming a carbon-containing film on a side wall of the silicon-containing film defining the recess portion in the chamber, and
(c) processing of etching a bottom portion of the recess portion where the carbon-containing film is formed, by using a plasma formed from a processing gas containing a hydrogen fluoride gas in the chamber.

### (Addendum 21)

An etching method including
(a) a step of disposing a substrate including a silicon-containing film having a recess portion and a mask, which has an opening exposing the recess portion, on the silicon-containing film on a first substrate support of a first processing chamber,
(b) a step of forming a carbon-containing film on a side wall of the silicon-containing film defining the recess portion in the first processing chamber, and
(c) a step of transporting the substrate from the first processing chamber to a second processing chamber via a transport chamber and disposing the substrate on a second substrate support of the second processing chamber, and
(d) a step of etching a bottom portion of the recess portion where the carbon-containing film is formed, by using a plasma formed from a processing gas containing a hydrogen fluoride gas in the second processing chamber.

Each of the above embodiments is described for the purpose of description, and is not intended to limit the scope of the present disclosure. Each of the above embodiments may be modified in various ways without departing from the scope and purpose of the present disclosure.

What is claimed is:

1. A plasma processing system comprising:
a first processing chamber having a first substrate support;
a second processing chamber that has a second substrate support and is different from the first processing chamber;
a transport chamber that is connected to the first processing chamber and the second processing chamber, and has a transport device; and
a controller,
wherein the controller executes
(a) processing of disposing a substrate including a silicon-containing film having a recess portion and a mask on the silicon-containing film on the first substrate support of the first processing chamber, in which the mask has an opening that exposes the recess portion,
(b) processing of forming a carbon-containing film on a side wall of the silicon-containing film defining the recess portion in the first processing chamber,
(c) processing of transporting the substrate from the first processing chamber to the second processing chamber via the transport chamber and disposing the substrate on the second substrate support, and
(d) processing of etching a bottom portion of the recess portion where the carbon-containing film is formed by using a plasma formed from a first processing gas containing a hydrogen fluoride gas in the second processing chamber.

2. The plasma processing system according to claim 1, wherein the controller executes processing of repeating a cycle including (a), (b), (c), and (d) a plurality of times.

3. The plasma processing system according to claim 1, wherein at least in (c), the controller controls a pressure in the transport chamber so that the pressure in the transport chamber is lower than a pressure in the first processing chamber and a pressure in the second processing chamber.

4. The plasma processing system according to claim 1, wherein the controller executes processing of forming the recess portion on the silicon-containing film and preparing the substrate including the silicon-containing film having the recess portion by etching using a plasma formed from a second processing gas containing a fluorine-containing gas in the second processing chamber or in a third processing chamber different from the second processing chamber before (a).

5. The plasma processing system according to claim 1, wherein a temperature of the first substrate support in the processing of (b) is higher than a temperature of the second substrate support in the processing of (c).

6. The plasma processing system according to claim 1, wherein the controller executes processing of forming the carbon-containing film with a third processing gas containing a carbon-containing gas in (b).

7. The plasma processing system according to claim 6, wherein the carbon-containing gas is a hydrocarbon gas.

8. The plasma processing system according to claim 6, wherein the third processing gas further contains a nitrogen-containing gas.

9. The plasma processing system according to claim 1, wherein in (b), the controller executes processing including
(b11) a step of supplying a precursor gas to the substrate and adsorbing the precursor gas to the side wall, and
(b12) a step of supplying a reaction gas to the substrate and forming the carbon-containing film by a reaction between the precursor gas and the reaction gas.

10. The plasma processing system according to claim 1, wherein (b) includes
(b1) a step of supplying a first film formation gas containing a first organic compound into the first processing chamber, and
(b2) a step of supplying a second film formation gas containing a second organic compound different from the first organic compound into the first processing chamber.

11. The plasma processing system according to claim 10, wherein (b2) forms the carbon-containing film by a reaction including polymerization of the first organic compound and the second organic compound.

12. The plasma processing system according to claim 1, wherein (d) further includes processing of enlarging a dimension of the portion that is etched in (d) in the recess portion.

13. The plasma processing system according to claim 1, wherein the first processing gas further contains a phosphorus-containing gas.

14. The plasma processing system according to claim 1, wherein the first processing gas further contains at least one gas selected from the group consisting of a carbon-containing gas, a halogen-containing gas, and a metal-containing gas.

15. The plasma processing system according to claim 14, wherein the processing of (d) is executed at a temperature of the second substrate support which is 0° C. or lower.

16. The plasma processing system according to claim 1, wherein the first processing chamber is coupled to an inductively coupled plasma generator,
the second processing chamber is coupled to a capacitively coupled plasma generator, and
in the processing of (b), the controller executes processing of forming a plasma by the inductively coupled plasma generator to form the carbon-containing film, and in the processing of (d), the controller executes processing of forming a plasma by the capacitively coupled plasma generator to etch the silicon-containing film.

17. The plasma processing system according to claim 1, wherein the silicon-containing film is a silicon oxide film, a silicon nitride film, a polycrystalline silicon film, or a stacked film including two or more of these.

18. The plasma processing system according to claim 1, wherein the mask is a carbon-containing film or a metal-containing film.

19. A plasma processing system comprising:
a first processing chamber having a first substrate support;
a second processing chamber that has a second substrate support and is different from the first processing chamber;
a transport chamber that is connected to the first processing chamber and the second processing chamber, and has a transport device; and
a controller,
wherein the controller includes
(a) processing of disposing a substrate including a silicon-containing film having a recess portion and a mask on the silicon-containing film on the first substrate support of the first processing chamber, in which the mask has an opening that exposes the recess portion,
(b) processing of forming a carbon-containing film on a side wall of the silicon-containing film defining the recess portion in the first processing chamber,
(c) processing of transporting the substrate from the first processing chamber to the second processing chamber via the transport chamber and disposing the substrate on the second substrate support, and
(d) processing of etching a bottom portion of the recess portion where the carbon-containing film is formed in the second processing chamber, and
the processing of (d) executes processing of repeating a cycle including
(d1) a step of exposing the substrate to a plasma formed from a fourth processing gas containing a hydrogen fluoride gas,
(d2) a step of exposing the substrate to a plasma formed from a fifth processing gas containing a fluorocarbon gas and/or a hydrofluorocarbon gas, and
(d3) a step of exposing the substrate to a plasma formed from a sixth processing gas containing a hydrogen-containing gas.

20. A plasma processing apparatus comprising:
a chamber;
a substrate support disposed in the chamber;
a plasma generator; and
a controller,
wherein the controller executes
(a) processing of disposing a substrate including a silicon-containing film having a recess portion and a mask, which has an opening exposing the recess portion, on the silicon-containing film on the substrate support, in which the mask has an opening that exposes the recess portion,
(b) processing of forming a carbon-containing film on a side wall of the silicon-containing film defining the recess portion in the chamber, and
(c) processing of etching a bottom portion of the recess portion where the carbon-containing film is formed, by using a plasma formed from a processing gas containing a hydrogen fluoride gas in the chamber.

21. An etching method comprising:
(a) a step of disposing a substrate including a silicon-containing film having a recess portion and a mask, which has an opening exposing the recess portion, on the silicon-containing film on a first substrate support of a first processing chamber in which the mask has an opening that exposes the recess portion;
(b) a step of forming a carbon-containing film on a side wall of the silicon-containing film defining the recess portion in the first processing chamber;
(c) a step of transporting the substrate from the first processing chamber to a second processing chamber via a transport chamber and disposing the substrate on a second substrate support of the second processing chamber; and
(d) a step of etching a bottom portion of the recess portion where the carbon-containing film is formed, by using a plasma formed from a processing gas containing a hydrogen fluoride gas in the second processing chamber.
